(19) United States
(12) Patent Application Publication
(10) Pub. No.: US 2017/0066930 A1
(43) Pub. Date: Mar. 9, 2017

(54) OLEOPHOBIC COATINGS ON AMORPHOUS CARBON COATED SURFACES OF AN ELECTRONIC DEVICE

(71) Applicant: APPLE INC., CUPERTINO, CA (US)

(72) Inventors: MATTHEW S. ROGERS, CUPERTINO, CA (US); SOYOUNG KIM, CUPERTINO, CA (US)

(21) Appl. No.: 15/256,067

(22) Filed: Sep. 2, 2016

Related U.S. Application Data
(60) Provisional application No. 62/213,843, filed on Sep. 3, 2015.

(51) Int. Cl. C09D 5/16; H05K 5/03; H04M 1/02; H05K 5/00

(52) U.S. Cl. CPC C09D 5/1662; H05K 5/0017; H05K 5/03; H04M 1/0202; G06K 9/00013

(57) ABSTRACT

An article includes an optically transparent substrate, an amorphous carbon layer formed on at least a portion of the optically transparent substrate, and an oleophobic layer attached to the optically transparent substrate by the amorphous carbon layer. The oleophobic coating, where present, may be attached to the substrate through the amorphous carbon layer. The article may be used as a cover for an electronic device.

### CROSS-REFERENCE TO RELATED APPLICATION

This application is a nonprovisional patent application of U.S. Patent Application No. 62/213,843, filed Sep. 3, 2015 and titled “Oleophobic Coatings on Amorphous Carbon Coated Surfaces of an Electronic Device,” the disclosure of which is hereby incorporated herein by reference in its entirety.

### FIELD

The disclosure relates generally to surface coatings on substrates, and more particularly to substrates having amorphous carbon and oleophobic coatings, where the oleophobic coating is attached to an underlying substrate through the amorphous carbon coating.

### BACKGROUND

Electronic devices often incorporate cover glass or other transparent substrates for use in displays, and in particular touch sensitive displays, camera lenses, sensors, input devices, and the like. In use, the cover glass and other transparent substrates accumulate dirt, oils and other deposits which can affect both the performance of the underlying display or sensor as well as the aesthetic quality of the device.

To address accumulated debris on a cover glass or transparent substrate, various surface treatments have been developed. In general, these treatments or coatings are hydrophobic and/or oleophobic in nature and act to repel water and/or oil and resist debris buildup. However, hydrophobic and/or oleophobic surface treatments have resulted in design challenges, particularly when applied to cover glass and other transparent substrates. Durability of these coatings may be limited.

### SUMMARY

An article includes an optically transparent substrate, an amorphous carbon layer formed on at least a portion of the optically transparent substrate, and an oleophobic layer attached to the optically transparent substrate by the amorphous carbon layer. The optically transparent substrate may be glass.

The oleophobic layer may comprise a fluoropolymer. A carbon atom of the fluoropolymer may be bonded directly to a carbon atom of the amorphous carbon layer.

The amorphous carbon layer may be between 5 and 50 nm thick. The amorphous carbon layer may have no or only trace amounts of Si groups. The amorphous carbon layer may be a diamond-like carbon layer.

A method includes disposing a bonding layer comprising amorphous carbon on at least a portion of a substrate, and disposing an oleophobic layer on the bonding layer, thereby attaching the oleophobic layer to the bonding layer. The method may further include forming a carbon-carbon bond between the oleophobic layer and the amorphous carbon.

The method may further include disposing an anti-reflective layer on the substrate, and the operation of disposing the bonding layer on at least the portion of the substrate may include disposing the bonding layer on the anti-reflective layer. The method may further include roughening the substrate prior to disposing the bonding layer on at least the portion of the substrate, or polishing the substrate prior to disposing the bonding layer on at least the portion of the substrate.

The oleophobic layer may comprise a fluoropolymer. The amorphous carbon may be a diamond-like carbon.

An electronic device may include a housing, one or more electronic components within the housing, a substrate defining an input surface of the electronic device, an amorphous carbon coating on the substrate, and an oleophobic coating chemically bonded to the amorphous carbon coating by a carbon-carbon bond. The amorphous carbon coating may comprise diamond-like carbon, and the oleophobic coating may comprise a fluoropolymer. An index of refraction of the amorphous carbon coating may substantially match an index of refraction of the oleophobic coating. The oleophobic coating may cover less than an entirety of the amorphous carbon coating.

In some cases, the substrate may be a transparent substrate covering a display region of the electronic device. In some cases, the substrate may define a surface of a fingerprint sensor.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 shows a sample electronic device;

FIG. 2A is a partial cross-sectional view of a substrate having an amorphous carbon layer, viewed along line CS-CS of FIG. 1;

FIG. 2B is a cross-sectional schematic view of a substrate having an amorphous carbon layer and an oleophobic layer, viewed along line CS-CS of FIG. 1;

FIG. 3A is a cross-sectional schematic view of a substrate with a silicon-based layer attaching a coating to the substrate, viewed along line CS-CS of FIG. 1;

FIG. 3B is a cross-sectional schematic view of a substrate coated with a fluoropolymer layer attached to the substrate via an intermediate amorphous carbon layer, viewed along line CS-CS of FIG. 1; and

FIG. 4 is a flow diagram of a method for coating a substrate with an amorphous carbon layer and an oleophobic layer.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates generally to surface coatings on substrates, and more particularly to amorphous carbon or diamond-like carbon deposited on transparent or translucent substrates. The disclosure also relates to transparent substrates having a deposited amorphous carbon layer as well as a layer or coating of hydrophobic and/or oleophobic material. “Oleophobic,” as used herein, is intended to encompass either or both of hydrophobic and oleophobic properties and/or materials.

Where the substrate exhibits both an amorphous carbon layer and an oleophobic layer, the amorphous carbon acts as an intermediate layer between the transparent substrate and the oleophobic coating. In this manner the amorphous carbon, for example a diamond-like carbon, acts as an attachment or linkage site between the oleophobic material and the underlying substrate.

In more detail, electronic device exteriors, and particularly cover glasses and other optically transparent exterior surfaces of an electronic device, are often formed from materials that are relatively strong but brittle. Thus, cover glasses and the like may fail under stress; a crack may propagate quickly and far through a cover glass, even a chemically strengthened cover glass or one made out of sapphire.

Embodiments herein provide a thin layer of amorphous carbon added to a substrate (e.g., a cover glass, housing, input structure, camera window, or the like) to reduce or prevent scratches, nicks, and/or cracks in the substrate. The amorphous carbon coating bonds to the substrate and acts as a barrier against external impact that could otherwise damage the substrate. Such coatings may be employed with other optically transparent substrates, like certain plastics, as well. Such coatings may cover some or all of the substrate, and may have a thickness that allows light transmission (e.g., they are optically transparent). Accordingly, the amorphous carbon coatings are typically between about 5 nm and about 100 nm thick, and more typically between about 5 nm and about 50 nm thick, and most typically between about 5 nm and about 15 nm thick.

Embodiments may also employ an oleophobic coating to enhance the appearance of a cover glass, housing, input structure, camera window, or the like. The oleophobic coating reduces and/or inhibits streaks, smears, marks, and the like on the cover glass or other optically transparent substrate. For example, the oleophobic coating may reject oil from a person's skin, thus reducing the presence of fingerprints, oil smears, and the like on the cover glass. Oleophobic coatings are typically between about 5 nm and about 100 nm thick, and more typically between about 5 nm and about 50 nm thick, and most typically between about 5 nm and about 15 nm thick. In some embodiments, the combination of amorphous carbon coating and oleophobic coating may be between about 10 nm and about 200 nm thick, or between about 10 nm and about 100 nm thick, or between about 10 nm and about 30 nm thick.

In certain embodiments, the amorphous carbon coating and the oleophobic coating may have matching or near-matching indices of refraction. This may reduce visibility of the coatings. Similarly, one or both of the coatings may have an index of refraction matching or near-matching that of the substrate. In some embodiments, one or both of the amorphous carbon coating and oleophobic coating may have indices of refraction sufficiently different from one another, or the substrate, that the combination of the two (or either layer alone) acts as an anti-reflective coating in addition to other properties described herein.

Also described herein are methods for bonding an oleophobic coating to an underlying substrate, where the oleophobic coating is attached directly to an amorphous carbon layer and thereby the underlying substrate. Amorphous carbon, for example diamond-like carbon, provides a highly durable attachment site for the oleophobic coating.

Amorphous carbon and oleophobic coated substrates may have significant durability and therefore increased utility. This durability may be a significant factor in the longevity of most electronic devices, particularly electronic devices having visual displays.

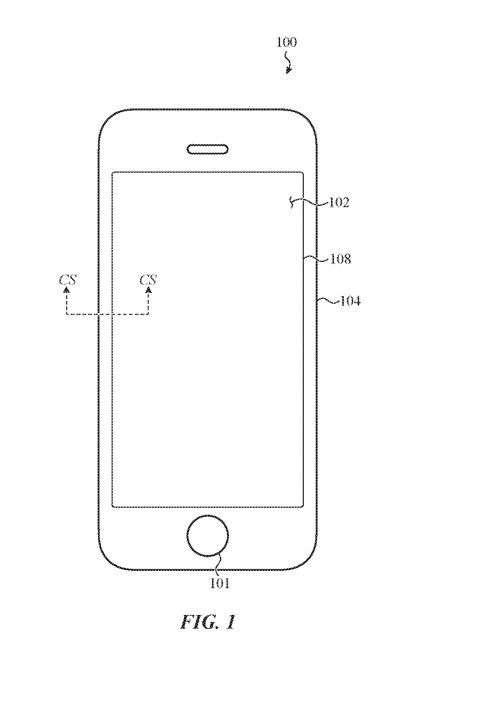

These and other embodiments are discussed below with reference to FIGS. 1-4. However, those skilled in the art will readily appreciate that the detailed description given herein with respect to these figures is for explanatory purposes only and should not be construed as limiting.

FIG. 1 illustrates an electronic device 100, shown here as a mobile phone, having at least one surface on which a coating is disposed in accordance with embodiments herein. The electronic device may include a cover 102 (e.g., a cover glass or other transparent substrate) coupled to a housing 104 about part or all of its edge in a manner that secures the cover glass to the electronic device. The housing 104 may be formed of a variety of different materials including plastics and other polymer materials, aluminum, steel, alloys, amorphous glass materials, composite materials, and combinations thereof. The cover 102 may be formed from or include any suitable transparent or translucent material, such as transparent glass, transparent plastic or polymer, or transparent crystalline material such as sapphire or sapphire glass.

Various electronic components for operation of the electronic device 100 may be located within the structure formed by the housing 104 and the cover 102. The cover 102 defines a display or visible region 108 through which a user may view graphical information generated by the electronic device 100. The cover 102 may also correspond to or define a touch- and/or force-sensitive input surface with which a user interacts to provide inputs to the electronic device 100.

The electronic device 100 also includes an input device, such as a button 101, that accepts user inputs (e.g., a button press or touch input) and causes the electronic device 100 to take an action or perform a function in response to the user input. The button 101, or a cap or cover of the button 101, may also act as a fingerprint sensing input surface. For example, the button 101 may include or be coupled to a fingerprint sensor. When a user places a finger in contact with the button 101, the fingerprint sensor may capture an image or representation of the user's fingerprint to compare with a reference image or representation. This process may be used to authenticate one or more users of the device, and successful authentication may “unlock” the electronic device 100 or otherwise enable certain functions and operations of the device.

User interactions with the device may leave scratches or smudges and other marks on the cover 102, the button 101, or other components of the device, such as the housing 104 or a camera lens (not shown). If such marks are on the cover 102, they may affect a visual quality of the display region 108. For example, images on a display below the cover 102 may be blurry, distorted, or occluded by the marks. Where such marks are on the button 101 (or a cover or cap of the button 101), the fingerprint sensing functionality may be reduced or limited. Where such marks are on a camera lens, quality of images taken by the camera may be reduced or limited.

To reduce scratches on a surface (e.g., the cover 102, the button 101, or any other component of the electronic device 100), an amorphous carbon layer, such as a diamond-like carbon, is deposited on the substrate. The amorphous carbon layer may be transparent, or substantially so, allowing light to pass therethrough. The amorphous carbon layer may be thick enough to provide anti-etching or anti-scratching properties to the underlying substrate. The amorphous carbon layer can be, for example, about 5 nm to about 100 nm thick. The amorphous carbon layer may be composed entirely or substantially entirely of carbon atoms. For example, the amorphous carbon layer may be at least 95% carbon by weight. In some cases, the amorphous carbon layer may be at least 99% carbon by weight. In some cases, the amorphous carbon layer includes only trace amounts of non-carbon elements, such as may be included or absorbed as a result of normal exposure to an ambient environment during manufacture, application, or use.

To reduce the likelihood of oils, smudges, liquid and the like collecting on a surface, (e.g., the cover 102, the button 101, or any other component of the electronic device 100), an oleophobic treatment or coating may be disposed on some or all of the surface on top of the amorphous carbon layer. In these embodiments, the amorphous carbon acts as both an anti-etching layer and a bonding layer between the surface and the oleophobic material. In these embodiments the oleophobic layer is durably linked to the underlying substrate through the carbon-rich environment of the amorphous carbon layer.

Oleophobic coatings for use herein may be composed of fluoropolymers. The chain length of each fluoropolymer, as attached to the amorphous carbon, has a number of repeating CF₂ units. This number may be between 10 and 40 CF₂ groups (e.g., (CF₂)ₙ, where n is between about 10 to about 40). In general, the fluoropolymer composed oleophobic coatings provide low coefficients of friction, resistance to high temperatures, and may act as a dielectric if desired or useful (although, in many cases, the dielectric effect may be negligible). The combination of oleophobic and amorphous carbon layers provides substrates with some or all of the foregoing properties while maintaining the substrate's transparency and reducing haze due to oil, liquid or other foreign matter.

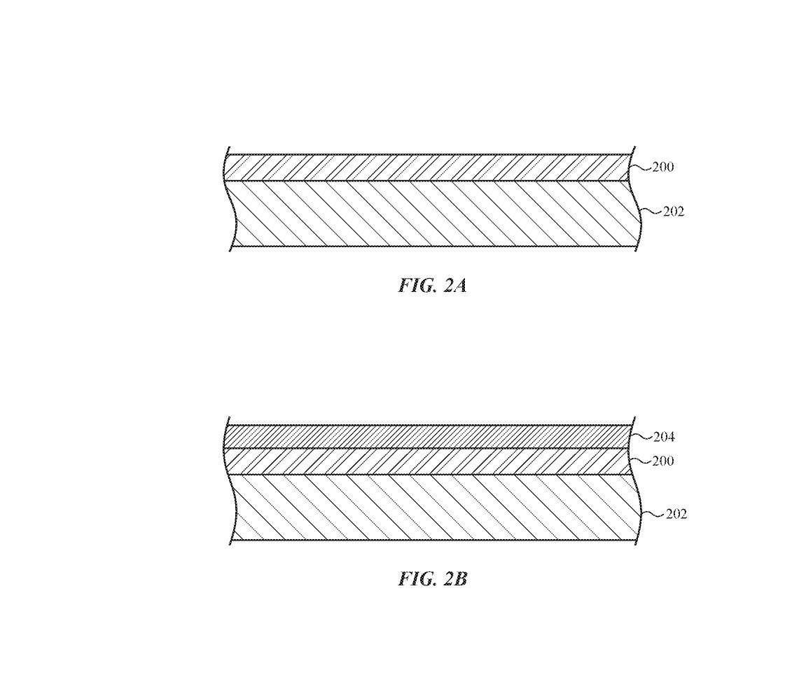

FIG. 2A is a cross-sectional schematic view of a substrate 202 with an amorphous carbon layer 200 deposited thereon, viewed along line CS-CS of FIG. 1A. The substrate 202 may correspond to the cover 102 of FIG. 1, a cap or cover of the button 101 of FIG. 1, or any other appropriate portion of an electronic device. The substrate 202 may be a transparent or translucent glass or sapphire (or any other appropriate material). The substrate 202, coated with the amorphous carbon layer 200, may be transparent and may have enhanced etch or scratch resistance as compared to the substrate 202 alone.

FIG. 2B is a cross-sectional schematic view of the substrate 202 having an oleophobic layer 204 attached to the substrate 202 via the amorphous carbon layer 200. The oleophobic layer 204 may be a fluoropolymer, and the amorphous carbon layer 200 may be a diamond-like carbon layer. In such cases, and as described in greater detail herein, the amorphous carbon layer 200 may act as a bond site for the fluoropolymer chains of the oleophobic layer 204.

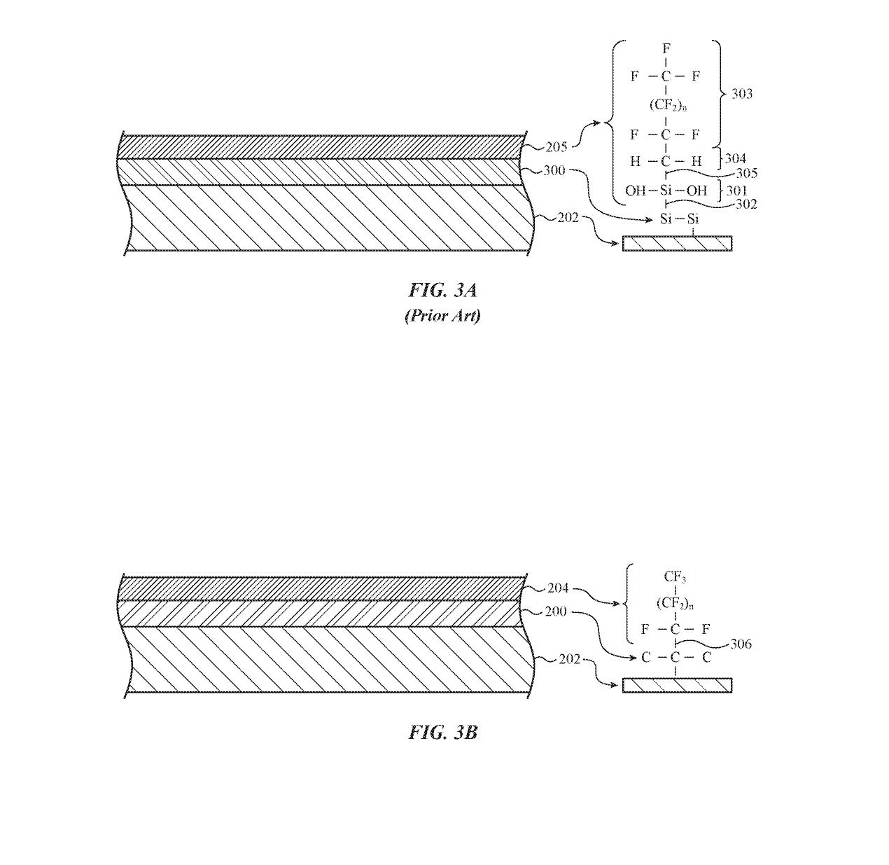

FIG. 3A is a cross-sectional schematic view of a substrate 202 with an oleophobic layer 205, using a SiO₂ based intermediate layer 300 to bond the oleophobic layer 205 to the substrate 202. FIG. 3A also depicts example chemical compositions of the oleophobic layer 205 and the intermediate layer 300, as well as the linkages (e.g., chemical bonds) between the materials of the various layers. The chemical compositions of the intermediate layer 300 and the oleophobic layer 205 are designed to couple the oleophobic layer 205 to the substrate 202. In particular, an oleophobic composition, such as a fluoropolymer chain, may not bond (or may not bond securely) directly to the material of the substrate 202. Accordingly, the intermediate layer 300 may have a composition that bonds to both the substrate 202 and the oleophobic layer 205, thus linking the oleophobic layer 205 to the substrate 202. In addition, the oleophobic layer 205 may include both a fluoropolymer chain, to provide oleophobic properties, as well as other chemical components (such as silanes) that form a better bond to the intermediate layer 300 than a fluoropolymer chain alone. The combination of the intermediate layer 300 and the additional chemical components of the oleophobic layer 205 serves to bond the oleophobic layer 205 to the substrate 202.

As noted, the oleophobic layer 205 in FIG. 3A may include one or more silane groups 301 that facilitate bonding between a fluoropolymer chain 303 and the SiO₂ based intermediate layer 300. Silanes are saturated chemical compounds that include one or more silicon atoms linked to each other or other chemical elements acting as the tetrahedral centers of multiple single bonds. However, the strength of the attachment between an oleophobic coating (e.g., the oleophobic layer 205) and a substrate (e.g., the substrate 202) is limited by the bond energy between the silicon-silicon (Si—Si) bonds 302 formed between the silanes of the oleophobic layer 205 and the silicon molecules of the intermediate layer 300. Silicon-based bonding provides approximately 52 kcal/mol bond energy (per bond), a significantly weaker bond energy than, for example, carbon based bonds (silicon-silicon bonding is typically about 60-65% the strength of carbon based bonding). Note that bond energy is the measure of the amount of energy required to break apart one mole of covalently bonded material, and expressed across the entire surface of a substrate represents a significant parameter in the ability of a coating to stay attached to the substrate. Because of the relatively low bonding energies of Si—Si linkage (and Si—C linkages 305), oleophobic coatings may tend to fail (e.g., separate from the underlying substrate) at these linkages. That is, the Si—Si or Si—C bonds may break, thus allowing the oleophobic fluoropolymer chain to detach from the substrate.

While FIG. 3A, shows a single silane group 301, any appropriate number of silane groups may be used, such as from 1 to 10 silane groups (or other groups including silicon atoms) between the substrate 202 and the fluoropolymer chain 303. Moreover, FIG. 3A illustrates a C—H group 304 between the fluoropolymer chain 303 and the silane group 301. The C—H group 304 may facilitate bonding between the fluoropolymer chain 303 and the silane group 301. For example, it may be a vestige of a chemical process used to join the fluoropolymer chain 303 to the silane group 301.

FIG. 3B is a cross-sectional schematic view of the substrate 202 having an oleophobic layer 204 attached to the substrate 202 via the amorphous carbon layer 200. FIG. 3B shows the same cross-section as FIG. 2A, and also depicts example chemical compositions of the oleophobic layer 204 and the amorphous carbon layer 200, as well as the linkages (e.g., chemical bonds) between the materials of the various layers. As described above, the intermediate layer is an amorphous carbon layer 200, depicted as a series of carbon atoms bonded via carbon-carbon bonds. The amorphous carbon layer 200 may be a diamond-like carbon (DLC) layer.

Whereas in FIG. 3A the fluoropolymer chain 303 was attached to the substrate 202 via a silane group, the fluoropolymer chain in FIG. 3B is attached to the substrate 202 via the amorphous carbon layer 200. Notably, a carbon atom of the fluoropolymer chain is bonded directly to a carbon atom of the amorphous carbon layer, forming a carbon-carbon bond 306. The bond energy of carbon-carbon bonds (approximately 83 kcal/mol) is higher than that of carbon-silicon bonds (approximately 52 kcal/mol), thereby providing a stronger chemical bond between the fluoropolymer chain and the underlying substrate 202. The higher strength of the carbon-carbon bonds may result in less detachment of the fluoropolymer chains, leading to a more durable and longer lasting oleophobic coating than one that relies on weaker chemical bonds, such as silicon-carbon bonds.

In some cases, as represented in FIG. 3B, each fluorocarbon polymer chain is directly bonded to a carbon atom in the amorphous carbon layer 200. These direct linkages between the carbon atoms of the fluoropolymer and those of the amorphous carbon layer eliminate the need for a silicon or silane active group attached to the fluoropolymer chains, and thus represent a significant improvement on attachment chemistry. For example, processing steps and cost associated with coupling silane groups 301 (FIG. 3A) to the fluoropolymer chain may be eliminated.

In some embodiments, at least 75% of the fluoropolymer chains may be attached directly to the amorphous carbon layer 200, and in more typical embodiments 80%, 85%, 90%, 95%, 96%, 97%, 98%, 99% or substantially all of the fluoropolymer is attached directly to the amorphous carbon and thereby to the underlying substrate 202.

It may be beneficial for the amorphous carbon layer 200 to include little or no silicon or SiO₂. As such, embodiments herein include amorphous carbon layers having less than 25% silicon atoms by weight (of the total intermediate layer weight), and more typically less than 10% silicon atoms by weight, and still more typically less than 5%, 4%, 3%, 2%, or 1% silicon atoms by weight of the total. In some embodiments the amorphous carbon layer has no silicon or only trace amounts of silicon by weight (“trace” being an amount due only to non-intentional inclusion via atmospheric occurrence). The quantity of silicon in the amorphous carbon layer can be determined using various forms of spectroscopy and the like.

The chemical compositions shown in FIGS. 3A-3B, and generally described herein, are intended as descriptive examples of chemical compositions and may represent idealized or exemplary structures. It will be understood that the actual chemical compositions, bonds, orientations, structures, and the like in physical implementations of these embodiments may vary from the ideals or from those depicted here. For example, the amorphous carbon layer 200 in FIG. 3B is illustrated as a single layer of carbon. However, the amorphous carbon layer 200 may have a depth of many more than one layer of carbon atoms. Also, while the carbon atoms in the amorphous carbon layer 200 in FIG. 3B are each depicted as being bonded to the underlying substrate 202, this need not be the case, as carbon atoms may be coupled to other carbon atoms (including, for example, carbon atoms of other fluoropolymer chains) in the amorphous matrix that makes up the amorphous carbon layer 200. Other variations, such as inclusions, impurities, and normal deviations in structure and composition, are also contemplated.

Embodiments herein also include substrates 202 having an anti-reflective coating (or layer) or protective coating (or layer). In one embodiment the anti-reflective coating and/or protective coating (e.g., to increase the hardness, stiffness, or toughness of the substrate) is first disposed on the substrate, followed by addition of the DLC or other amorphous carbon layer and an oleophobic coating. In this way substrates can be formed with properties desired for the intended or end use. For example, a substrate 202 could include an inner anti-reflective layer (not shown) on the substrate 202, a middle or intermediate amorphous carbon layer (e.g., the intermediate layer 200) over the anti-reflective layer, and an outer oleophobic layer (e.g., the oleophobic layer 204) over the intermediate layer. In other embodiments, one or both of the oleophobic and intermediate layers may also have anti-reflective properties.

Embodiments herein also include instances where only portions of the substrate are coated with an amorphous carbon layer. For example, in some embodiments, one or more portions (e.g., less than an entirety of a surface) of the substrate particularly prone to scratching or other damage may be coated with an amorphous carbon layer. For example, the edges of the substrate may be so coated. In other embodiments, portions of the substrate through which a display is visible may be coated with an amorphous carbon layer in order to prevent scratches or other damage from obscuring or otherwise negatively impacting viewing of the display. Further, embodiments herein include substrates where only a portion of the amorphous carbon is further coated with an oleophobic coating, such that a substrate may employ the amorphous carbon for anti-scratch purposes in one area and both the amorphous carbon and oleophobic coating for anti-scratch and oil/deposit prevention in another area (for example where one area of the substrate is used for touch-sensitive applications and the other in a non-critical or non-aesthetic function).

Additionally, an electronic device may have multiple substrates, where some substrates are coated using embodiments as described herein (e.g., amorphous carbon or amorphous carbon and oleophobic coatings) and other substrates employ more conventional SiO₂ intermediate layers. For example, some substrates or portions of substrate may not benefit from an amorphous carbon layer or amorphous carbon and oleophobic coating. For example, amorphous carbon may not bond securely to some substrates or portions thereof. In such cases, the other attachment chemistries or techniques may be used.

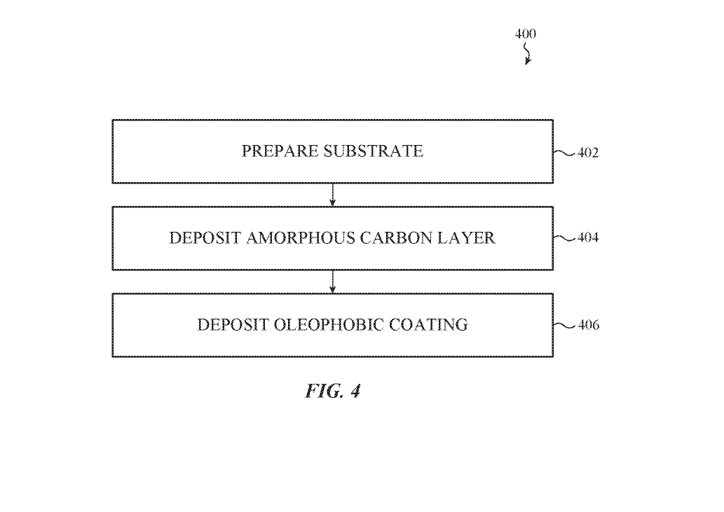

FIG. 4 is a block diagram of a method 400 for coating a substrate, for example the cover 102 of the electronic device 100 of FIG. 1. Method 400 includes the operation 402 of preparing or obtaining a substrate and the operation 404 of forming an amorphous carbon layer on the substrate. Embodiments herein also include the operation 406 of forming an oleophobic coating on the substrate through attachment with the amorphous carbon layer.

In operation 402, preparation of the substrate may include cleaning and other surface preparations, for example, using water or a chemical solvent, heat treatment, polishing, and the like to prepare the substrate for application of the amorphous carbon layer (or a layer or coating that is to be applied prior to application of the amorphous carbon layer). Preparation of the substrate may also include roughening the substrate to create surface features to which the amorphous carbon layer (or another preliminary or intermediate layer) may more easily or securely bond. Roughening the substrate may include grinding, sanding, etching (e.g., laser, chemical, or otherwise), abrasive blasting, or the like.

Preparation of the substrate may also or alternatively include polishing or otherwise smoothing the substrate (e.g., with lapping, buffing, sanding, or the like), which may enhance optical quality of the substrate. In one embodiment the substrate is glass or sapphire, cut to size for a particular application, e.g., cut to a size of a cover for an electronic device.

In operation 404 the amorphous carbon layer is deposited, formed, applied, or otherwise disposed on the substrate. Disposing the amorphous carbon layer on the substrate may utilize any of a number of different methodologies, including radio frequency magnetron sputtering, low-pressure dielectric barrier discharge, biased-plasma or plasma beam deposition, vapor deposition or other chemical deposition techniques, cathodic arc sputtering, low or high energy vacuum deposition, or high-energy ion-beam deposition.

The amorphous carbon layer may contain little or no silicon. For example, the amorphous carbon layer may have less than 25% silicon by weight, or less than 5%, 4%, 3%, 2%, or 1% silicon by weight. In some embodiments the amorphous carbon layer is optically transparent and has a thickness selected from a range from about 5 nm to about 100 nm. In some embodiments the layer is about 5 nm to about 50 nm in thickness, and in others the layer is between about 5 nm and about 15 nm thick. In certain embodiments the thickness of the amorphous carbon layer is sufficient to provide attachment points for the oleophobic coating on the substrate and, in some cases, act as a barrier against physical damage to the substrate. The thickness of the amorphous carbon layer may vary by less than about 25%, or less than about 10%, or less than about 5% throughout the layer.

In operation 406 the oleophobic coating is deposited, formed, applied, or otherwise disposed on the amorphous carbon layer. The oleophobic layer may be disposed on the amorphous carbon-substrate by dipping, spraying, layering, and the like, as well as any methodology discussed above with respect to disposing the amorphous carbon layer on the substrate. The oleophobic layer may be any appropriate material or composition, such as a fluoropolymer.

In typical embodiments the oleophobic coating is between about 5 nm and 50 nm, and more typically about 5 to 15 nm in thickness. In some cases the oleophobic coating is between about 5 nm and about 10 nm. The thickness of the oleophobic coating may vary by less than about 25%, or less than about 10%, or less than about 5% throughout the coating.

Several of the foregoing examples describe the amorphous carbon layer and oleophobic coating disposed on a transparent cover for an electronic device. However, the amorphous carbon and oleophobic layers may also be used on non-transparent materials, such as metals (e.g., aluminum, steel, alloys, amorphous metals), ceramics (e.g., zirconia, alumina, sialon), plastics, crystalline materials (e.g., sapphire, quartz), and the like. In such cases, the oleophobic coatings may help prevent or reduce the accumulation or appearance of smudges, oil, or water, while the amorphous carbon assists in attaching the oleophobic coatings to the non-transparent materials and also increases scratch resistance. Such materials, coated with the amorphous carbon and/or oleophobic layers, may be used for any appropriate use, such as electronic device housings, input devices (e.g., button surfaces, fingerprint sensors, keycaps), camera lenses or other optical elements, or the like.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. As one non-limiting example, other electronic devices may employ embodiments described herein; sample electronic devices include tablet computing devices, wearable electronic devices (e.g., watches, glasses, jewelry, and so on), computers, digital media players, touch screens and pads, and so on. It will be apparent to one of ordinary skill in the art that many modifications and variations are possible in view of the above teachings.

1. An article, comprising:
an optically transparent substrate;
a diamond-like carbon layer formed on at least a portion of the optically transparent substrate; and
an oleophobic layer attached to the optically transparent substrate by the diamond-like carbon layer.

2. The article of claim 1, wherein the oleophobic layer comprises a fluoropolymer.

3. The article of claim 2, wherein a carbon atom of the fluoropolymer is bonded directly to a carbon atom of the diamond-like carbon layer.

4. The article of claim 1, wherein the optically transparent substrate is glass.

5. The article of claim 1, wherein the diamond-like carbon layer is between 5 and 50 nm thick.

6. (canceled)

7. The article of claim 1, wherein the diamond-like carbon layer has no or trace amounts of Si groups.

8. A method, comprising:
disposing a bonding layer comprising amorphous carbon on at least a portion of a substrate; and
disposing an oleophobic layer on the bonding layer, thereby attaching the oleophobic layer to the bonding layer.

9. The method of claim 8, further comprising forming a carbon-carbon bond between the oleophobic layer and the amorphous carbon.

10. The method of claim 8, wherein the oleophobic layer comprises a fluoropolymer.

11. The method of claim 10, wherein the amorphous carbon is a diamond-like carbon.

12. The method of claim 8, further comprising:
disposing an anti-reflective layer on the substrate; wherein
the operation of disposing the bonding layer on at least the portion of the substrate comprises disposing the bonding layer on the anti-reflective layer.

13. The method of claim 8, further comprising roughening the substrate prior to disposing the bonding layer on at least the portion of the substrate.

14. The method of claim 8, further comprising polishing the substrate prior to disposing the bonding layer on at least the portion of the substrate.

15. An electronic device, comprising:
a housing;
one or more electronic components within the housing;
a substrate defining an input surface of the electronic device;
an amorphous carbon coating on the substrate; and
an oleophobic coating chemically bonded to the amorphous carbon coating by a carbon-carbon bond.

16. The electronic device of claim 15, wherein:
the amorphous carbon coating comprises diamond-like carbon; and
the oleophobic coating comprises a fluoropolymer.

17. The electronic device of claim 15, wherein the substrate is a transparent substrate covering a display region of the electronic device.

18. The electronic device of claim 15, wherein the substrate defines a surface of a fingerprint sensor.

19. The electronic device of claim 15, wherein an index of refraction of the amorphous carbon coating substantially matches an index of refraction of the oleophobic coating.

20. The electronic device of claim 15, wherein the oleophobic coating covers less than an entirety of the amorphous carbon coating.

21. The article of claim 1, wherein the optically transparent substrate is crystalline.
